(19) United States
(12) Patent Application Publication
(10) Pub. No.: US 2019/0127580 A1
(43) Pub. Date: May 2, 2019

(54) Semiconductor Encapsulating Resin Composition and Semiconductor Device

(71) Applicant: Shin-Etsu Chemical Co., Ltd., Tokyo (JP)

(72) Inventors: Shoichi Osada, Annaka-shi (JP); Norifumi Kawamura, Annaka-shi (JP); Masahiro Kaneta, Annaka-shi (JP); Ryuhei Yokota, Annaka-shi (JP)

(73) Assignee: Shin-Etsu Chemical Co., Ltd., Tokyo (JP)

(21) Appl. No.: 16/161,516

(22) Filed: Oct. 16, 2018

(30) Foreign Application Priority Data
Oct. 27, 2017 (JP) 2017-207850

(51) Int. Cl. C08L 79/08; C08L 63/00; C08G 18/02; C08K 9/06; C08K 5/544; C08K 5/5419; H01L 23/29

(52) U.S. Cl. CPC C08L 79/08; C08L 63/00; C08G 18/02; H01L 23/296; C08K 5/5442; C08K 5/5419; C08K 9/06

(57) ABSTRACT

A resin composition comprising a thermosetting resin, an inorganic filler and an organosilicon compound of specific structure is provided. The inorganic filler is briefly treated with the organosilicon compound to have a high affinity to the resin. The composition is improved in flow and impact resistance and suited for encapsulating semiconductor devices.

### CROSS-REFERENCE TO RELATED APPLICATION

This non-provisional application claims priority under 35 U.S.C. § 119(a) on Patent Application No. 2017-207850 filed in Japan on Oct. 27, 2017, the entire contents of which are hereby incorporated by reference.

### TECHNICAL FIELD

This invention relates to a semiconductor encapsulating resin composition and a semiconductor device encapsulated therewith.

### BACKGROUND ART

Resin encapsulation lies in the current mainstream of semiconductor devices including diodes, transistors, ICs, LSIs and VLSIs. In a common practice, semiconductor devices are encapsulated with a resin composition comprising an epoxy resin and an inorganic filler because the epoxy resin is superior in molding, adhesion, electric properties, mechanical properties and moisture resistance to other thermosetting resins. Recently, it is under study that resin materials having high thermal stability and low dielectric constant like cyanate resins and bismaleimide resins are used as encapsulants for power devices and high-frequency devices.

When semiconductor devices are encapsulated with resin compositions, the transfer molding method of heating the resin composition and casting the melt into a mold is generally used. In the transfer molding, it is required that the device interior be free of voids and the device wires be little deformed. The encapsulated device should protect the inside semiconductor chip and wires from external physical impacts and thermal shocks.

These requirements may be met by previous surface treatment of inorganic fillers for the purpose of improving the interfacial wetting between the thermosetting resin and the inorganic filler. For example, Patent Document 1 discloses that the surface treatment of an inorganic filler with N-phenyl-y-aminopropyltrimethoxysilane makes an epoxy resin composition (containing the treated filler) highly reactive and provides a cured product thereof with a high stiffness, leading to improved mold release properties.

Patent Document 2 discloses the surface treatment of inorganic filler by spraying a silane coupling agent or an alcohol solution thereof to an inorganic filler under agitation, continuing further agitation, and allowing the filler to stand at room temperature or heating at an elevated temperature.

These techniques, however, have the problems of long manufacture time and low productivity. Since N-phenyl-y-aminopropyltrimethoxysilane is slow in hydrolysis, pretreatment such as holding at room temperature for 24 to 48 hours, or holding at an elevated temperature of 50 to 80° C. for 1 to 4 hours is necessary to induce reaction with the inorganic filler surface. Thus an extra step for the pretreatment must be involved.

### CITATION LIST

Patent Document 1: JP-A H09-057749

Patent Document 2: JP-A 2002-241585

### DISCLOSURE OF INVENTION

An object of the invention is to provide a resin composition comprising a thermosetting resin and an inorganic filler wherein the inorganic filler is briefly treated to have a high affinity to the resin so that the composition is improved in flow and impact resistance, and a semiconductor device encapsulated with the resin composition.

The inventors have found that the outstanding problems are overcome by a resin composition comprising (A) a thermosetting resin, (B) an inorganic filler, and (C) an organosilicon compound of specific structure, which is suited for semiconductor encapsulation.

In one aspect, the invention provides a semiconductor encapsulating resin composition comprising (A) a thermosetting resin, (B) an inorganic filler, and (C) an organosilicon compound having the formula (1) as essential components.

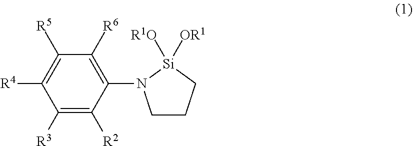

Herein R¹ is a C₁-C₃ alkyl group, R², R³, R⁴, R⁵ and R⁶ are each independently selected from hydrogen, C₁-C₃ alkyl groups, and C₁-C₃ alkoxy groups.

In a preferred embodiment, component (C) contains an organosilicon compound having the formula (2):

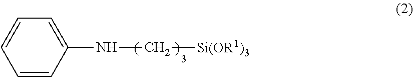

wherein R¹ is a C₁-C₃ alkyl group, in addition to the organosilicon compound having formula (1).

The thermosetting resin is preferably at least one member selected from among epoxy resins, cyanate resins, and bismaleimide resins.

The resin composition may further comprise (D) a curing agent and (E) a cure accelerator.

In another aspect, the invention provides a semiconductor device encapsulated with the resin composition defined herein.

### ADVANTAGEOUS EFFECTS OF INVENTION

Since an inorganic filler is briefly treated so as to have a high affinity to a thermosetting resin, the resin composition is improved in flow and impact resistance. The resin composition is thus suited for encapsulating semiconductor devices.

### BRIEF DESCRIPTION OF DRAWINGS

FIGS. 1A and 1B schematically illustrate a test specimen used in a three-point bending test for measuring fracture toughness.

### DESCRIPTION OF PREFERRED EMBODIMENTS

One embodiment of the invention is a semiconductor encapsulating resin composition comprising (A) a thermosetting resin, (B) an inorganic filler, and (C) an organosilicon compound having the formula (1) as essential components.

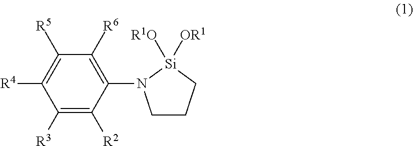

Herein R¹ is a C₁-C₃ alkyl group, R², R³, R⁴, R⁵ and R⁶ are each independently selected from hydrogen, C₁-C₃ alkyl groups, and C₁-C₃ alkoxy groups. These components are described in detail.

### (A) Thermosetting Resin

Component (A) is a thermosetting resin, which is suited for semiconductor encapsulation. Exemplary thermosetting resins include epoxy resins, cyanate (ester) resins, bismaleimide resins, benzoxazine resins and silicone resins. Inter alia, epoxy resins, cyanate resins, and bismaleimide resins are preferred, with the epoxy resins being most preferred.

Epoxy Resins

Suitable epoxy resins include novolak epoxy resins, cresol novolak epoxy resins,, triphenolalkane epoxy resins, aralkyl epoxy resins, biphenyl structure-containing aralkyl epoxy resins, biphenyl epoxy resins, dicyclopentadiene epoxy resins, heterocyclic epoxy resins, naphthalene ring-containing epoxy resins, bisphenol A epoxy resins, bisphenol F epoxy resins, stilbene epoxy resins, triglycidyl isocyanate compounds and monoallyl diglycidyl isocyanate compounds, which may be used singly or in admixture.

Also included in the epoxy resins are copolymers obtained from hydrosilylation reaction of an alkenyl-containing epoxy compound with a hydrogenorganopolysiloxane having the average formula (3):

HₐR_{b}SiO_{(4-a-b)/2} (3)

wherein R is a substituted or unsubstituted C₁-C₁₀ monovalent hydrocarbon group, a is a number from 0.01 to 1, b is a number from 1 to 3, and a+b is from 1.01 to less than 4.

The alkenyl-containing epoxy compound may be obtained, for example, by epoxidizing an alkenyl-containing phenolic resin with epichlorohydrin, or by partially reacting a well-known epoxy compound with 2-allylphenol. Such epoxy compounds are represented, for example, by the average formula (4).

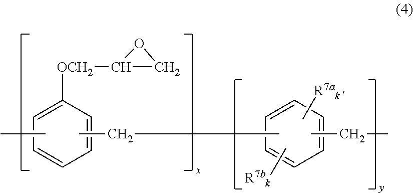

In formula (4), R^{7a} is a C₃-C₁₅, preferably C₃-C₅, aliphatic monovalent hydrocarbon group having an alkenyl moiety, R^{7b} is a glycidyloxy group or a group of the formula: —OCH₂CH(OH)CH₂OR′ wherein R′ is a C₃-C₁₀, preferably C₃-C₅, monovalent hydrocarbon group having an alkenyl moiety, k is equal to 1, k′ is equal to 0 or 1, x is a positive number of 1 to 30, and y is a positive number of 1 to 3.

Examples of the epoxy compound having average formula (4) are shown below.

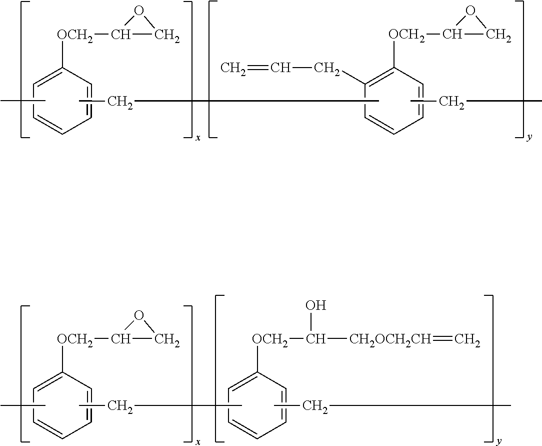

Herein x and y are positive numbers in the range: 1<x<10 and 1<y<3.

The hydrogenorganopolysiloxane having average formula (3) has at least one SiH group in the molecule. In formula (3), R is a C₁-C₁₀, preferably C₁-C₆, monovalent hydrocarbon group, examples of which include alkyl groups such as methyl, ethyl, propyl, isopropyl, butyl, isobutyl, tert-butyl, pentyl, neopentyl, hexyl, octyl, nonyl and decyl, aryl groups such as phenyl, tolyl, xylyl, and naphthyl, and aralkyl groups such as benzyl, phenylethyl, and phenylpropyl. In these groups, at least one (one or more or even all) hydrogen may be substituted by halogen such as fluorine, bromine or chlorine. Preferably R is methyl, ethyl or phenyl.

The hydrogenorganopolysiloxane having average formula (3) may be straight, branched or cyclic. Exemplary are those represented by the following formulae (a), (b) and (c).

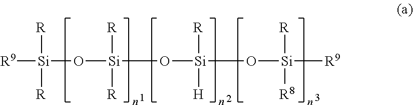

In formula (a), R is each independently as defined above, R⁹ is hydrogen or a group selected from the same groups as R, n¹ is an integer of 5 to 200, n² is an integer of 0 to 2, n³ is an integer of 0 to 10, and R⁸ is a group of the following formula:

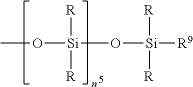

wherein R and R⁹ are as defined above, and n⁵ is an integer of 1 to 10. The compound having formula (a) should contain at least one silicon-bonded hydrogen atom.

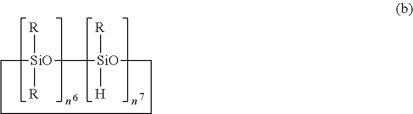

In formula (b), R is each independently as defined above, n⁶ is an integer of 1 to 10, and n⁷ is 1 or 2. The compound having formula (b) should contain at least one silicon-bonded hydrogen atom.

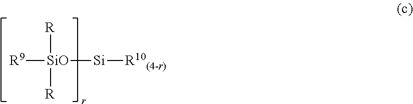

In formula (c), R and R⁹ are as defined above, r is an integer of 0 to 3, R¹⁰ is hydrogen or a C₁-C₁₀ monovalent hydrocarbon group which may contain an oxygen atom. The compound having formula (c) should contain at least one silicon-bonded hydrogen atom.

Of the hydrogenorganopolysiloxanes, dual end hydrogenmethylpolysiloxanes and dual end hydrogenmethylphenylpolysiloxanes are preferred. For example, the following compounds are preferred.

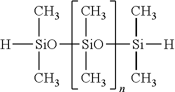

Herein n is an integer of 20 to 100.

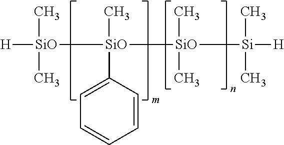

Herein m is an integer of 1 to 10, and n is an integer of 10 to 100.

Cyanate Resins

Suitable cyanate ester resins include bis(4-cyanatophenyl)methane, bis(3 -methyl-4-cyanatophenyl)methane, bis(3 -ethyl-4-cyanatophenyl)methane, bis(3,5-dimethyl-4-cyanatophenyl)methane, 1,1-bis(4-cyanatophenyl)ethane, 2,2-bis(4-cyanatophenyl)propane, 2,2-bis(4-cyanatophenyl)-1,1,1,3,3,3-hexafluoropropane, di(4-cyanatophenyl)thioether, 1,3-dicyanatobenzene, 1,4-dicyanatobenzene, 2-tert-butyl-1,4-dicyanatobenzene, 2,4-dimethyl-1,3-dicyanatobenzene, 2,5-di-tert-butyl-1,4-dicyanatobenzene, tetramethyl-1,4-dicyanatobenzene, 1,3,5-tricyanatobenzene, 2,2′-dicyanatobiphenyl, 4,4′-dicyanatobiphenyl, 3,3′,5,5′-tetramethyl-4,4′-dicyanatobiphenyl, 1,3-dicyanatonaphthalene, 1,4-dicyanatonaphthalene, 1,5-dicyanatonaphthalene, 1,6-dicyanatonaphthalene, 1,8-dicyanatonaphthalene, 2,6-dicyanatonaphthalene, 2,7-dicyanatonaphthalene, 1,3,6-tricyanatonaphthalene, bis(4-cyanatophenyl)methane, 2,2-bis(4-cyanatophenyl)propane, 1,1,1-tris(4-cyanatophenyl)ethane, bis(4-cyanatophenyl) ether, 4,4′-(1,3-phenylenediisopropylidene)diphenyl cyanate, bis(4-cyanatophenyl)thioether, bis(4-cyanatophenyl)sulfone, tris(4-cyanatophenyl)phosphine, tris(4-cyanatophenyl) phosphate, phenol novolak cyanates, cresol novolak cyanates, dicyclopentadiene novolak cyanates, phenyl aralkyl cyanate esters, biphenyl aralkyl cyanate esters, and naphthalene aralkyl cyanate esters. Inter alia, phenol novolak cyanates, dicyclopentadiene novolak cyanates, phenyl aralkyl cyanate esters, and biphenyl aralkyl cyanate esters are preferred. These cyanate ester compounds may be used singly or in admixture.

Bismaleimide Resins

Suitable bismaleimide resins include N,N′-4,4′-diphenylmethanebismaleimide and N,N′-(3,3′-dimethyl-4,4′-diphenylmethane)bismaleimide, with N,N′-4,4′-diphenylmethanebismaleimide being preferred.

### (B) Inorganic Filler

Component (B) is an inorganic filler, which is selected from those fillers suitable for use in semiconductor-encapsulating resin compositions. Suitable fillers include silica such as fused silica and crystalline silica, spherical cristobalite, alumina, magnesium oxide, silicon nitride, aluminum nitride, boron nitride, titanium oxide, and glass fibers.

Of these, inorganic fillers having silanol groups on their surface such as silica and cristobalite are preferred. With respect to the size and shape of the inorganic filler, an average particle size of 3 to 40 μm, especially 5 to 30 μm is desirable from the standpoints of molding and flow. Notably, the average particle size refers to a cumulative volume base average value (or median diameter) in particle size distribution measurement by the laser diffraction method.

The inorganic filler (B) is preferably used in an amount of 300 to 2,000 parts, more preferably 600 to 1,800 parts by weight per 100 parts by weight of the thermosetting resin (A). As long as the amount of the filler is at least 300 parts, which indicates a relatively low content of the resin in the resin composition, the resin composition has a coefficient of thermal expansion which is not excessively high, indicating mitigated thermal stress to the package. If the amount of the filler exceeds 2,000 parts, there may arise concerns including incomplete filling and wire deformation due to a decline of flow and increased thermal stress due to an increase of elastic modulus.

### (C) Organosilicon Compound

Component (C) is an organosilicon compound having the formula (1).

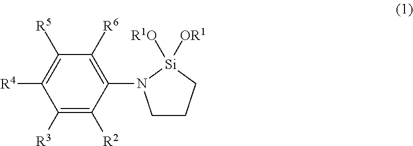

The compound quickly reacts with active hydrogen, typically hydroxyl groups, on the surface of the inorganic filler (B), to enhance its affinity to the thermosetting resin (A).

In formula (1), R¹ is a C₁-C₃ alkyl group, such as methyl, ethyl, n-propyl and isopropyl, with methyl being preferred. R², R³, R⁴, R⁵ and R⁶ are each independently selected from hydrogen, C₁-C₃ alkyl groups, and C₁-C₃ alkoxy groups. Examples of the C₁-C₃ alkyl groups represented by R² to R⁶ are as exemplified for R¹.

One exemplary method for preparing the organosilicon compound having formula (1) is by heating an alkoxysilane having formula (2):

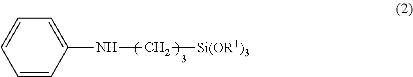

wherein R¹ is a C₁-C₃ alkyl group, in the presence of a basic compound such as an alkali metal alkoxide.

The organosilicon compound having formula (1) may be used alone or in admixture with another organosilicon compound (alkoxysilane) having formula (2). In the latter case, the alkoxysilane of formula (2) is preferably present in an amount of up to 30% by weight of the mixture, the amount being more preferably 0 to 10% by weight, even more preferably 0.01 to 8% by weight.

The amount of component (C) used is preferably 0.05 to 5.0 parts, more preferably 0.1 to 1.0 part, even more preferably 0.2 to 0.5 part by weight per 100 parts by weight of the inorganic filler (B).

In addition to components (A) to (C), the resin composition may further contain (D) a curing agent and (E) a cure accelerator.

### (D) Curing Agent

Component (D) is a curing agent which reacts with the thermosetting resin (A) to form a cured product. Suitable curing agents include phenolic resin base curing agents, acid anhydride base curing agents, and amine base curing agents. Examples of the phenolic resin base curing agents include phenol novolak resins, naphthalene ring-containing phenolic resins, aralkyl type phenolic resins, triphenol alkane type phenolic resins, biphenyl structure-containing aralkyl type phenolic resins, biphenyl type phenolic resins, alicyclic phenolic resins, heterocyclic phenolic resins, naphthalene ring-containing phenolic resins, bisphenol A, and bisphenol F. Examples of the acid anhydride base curing agents include 3,4-dimethyl-6-(2-methyl-1-propenyl)-1,2,3,6-tetrahydrophthalic anhydride, 1-isopropyl-4-methyl-bicyclo[2.2.2]oct-5-ene-2,3-dicarboxylic anhydride, methyltetrahydrophthalic anhydride, methylhexahydrophthalic anhydride, hexahydrophthalic anhydride, methylhimic anhydride, pyromellitic dianhydride, maleic alloocimene, benzophenone tetracarboxylic dianhydride, 3,3′,4,4′-biphenyltetrabisbenzophenone tetracarboxylic dianhydride, (3,4-dicarboxyphenyl) ether dianhydride, bis(3,4-dicarboxyphenyl)methane dianhydride, and 2,2-bis(3,4-dicarboxyphenyl)propane dianhydride. Examples of the amine base curing agents include aromatic diaminodiphenylmethane compounds such as 3,3′-diethyl-4,4′-diaminophenylmethane, 3,3′,5,5′-tetramethyl-4,4′-diaminophenylmethane, and 3,3′,5,5′-tetraethyl-4,4′-diaminophenylmethane, 2,4-diaminotoluene, 1,4-diaminobenzene, and 1,3-diaminobenzene. These curing agents may be used singly or in admixture.

The curing agent (D) is preferably used in an amount of 0.1 to 2 moles, more preferably 0.3 to 1.2 moles per mole of reactive functional groups in the thermosetting resin (A).

### (E) Cure Accelerator

Component (E) is a cure accelerator, which serves to accelerate the cure reaction between components (A) and (D). Suitable cure accelerators include phosphorus compounds such as triphenylphosphine, tributylphosphine, tri(p-methylphenyl)phosphine, tri(nonylphenyl)phosphine, triphenylphosphine-triphenylborane, tetraphenylphosphine-tetraphenyl borate, tertiary amine compounds such as triethylamine, benzyldimethylamine, α-methylbenzyldimethylamine, 1,8-diazabicyclo[5.4.0]undecene-7, imidazole compounds such as 2-methylimidazole, 2-phenylimidazole, and 2-phenyl-4-methylimidazole, peroxides, urea compounds and salicylic acid.

The accelerator (E) is preferably used in an amount of 0.0001 to 0.1 mole per mole of reactive functional groups in the thermosetting resin (A).

### Other Components

In the resin composition, various additives such as parting agents, flame retardants, ion trapping agents, tackifiers, and pigments may be added, if necessary.

Parting agents are not particularly limited and any well-known parting agents may be used. Suitable parting agents include waxes such as carnauba wax, rice wax, polyethylene, polyethylene oxide, montanic acid, esters of montanic acid with saturated alcohols, 2-(2-hydroxyethylamino)ethanol, and ethylene glycol, and glycerol; stearic acid, stearates, stearamide, ethylene bisstearamide, and copolymers of ethylene and vinyl acetate. These compounds may be used singly or in admixture.

Flame retardants are not particularly limited and any well-known retardants may be used. Suitable flame retardants include phosphazene compounds, silicone compounds, zinc molybdate-carrying talc, zinc molybdate-carrying zinc oxide, aluminum hydroxide, magnesium hydroxide, molybdenum oxide, and antimony trioxide, which may be used singly or in admixture.

Ion trapping agents are not particularly limited and any well-known trapping agents may be used. Suitable ion trapping agents include hydrotalcites, bismuth hydroxide, and rare earth oxides, which may be used singly or in admixture.

Tackifiers are not particularly limited and any well-known tackifiers may be used.
Suitable tackifiers include γ-glycidoxypropyltrimethoxysilane,
γ-glycidoxypropylmethyldiethoxysilane, γ-glycidoxypropyltriethoxysilane,
p-styryltrimethoxysilane, γ-methacryloxypropylmethyldimethoxysilane,
γ-methacryloxypropyltrimethoxysilane, γ-methacryloxypropylmethyldiethoxysilane,
γ-methacryloxypropyltriethoxysilane, γ-acryloxypropyltrimethoxysilane,
N-β-(aminoethyl)-γ-aminopropylmethyldimethoxysilane,
N-β-(aminoethyl)-γ-aminopropyltrimethoxysilane,
N-β-(aminoethyl)-γ-aminopropyltriethoxysilane, γ-aminopropyltrimethoxysilane,
γ-aminopropyltriethoxysilane, γ-mercaptopropylmethyldimethoxysilane,
γ-mercaptopropyltrimethoxysilane, bis(triethoxypropyl)tetrasulfide,
γ-isocyanatopropyltriethoxysilane, which may be used singly or in admixture.

### Preparation of Resin Composition

The method for preparing the resin composition defined above is not particularly limited. The resin composition is generally prepared by mixing components (A), (B), (C) and optional components. The mixing step preferably includes a first step of mixing two components: (B) and (C) and a second step of adding component (A) to the premix and mixing them. The method involving mixing components in two stages is advantageous in that the organosilicon compound having formula (1) effectively reacts with reactive functional groups (e.g., silanol) on the surface of the inorganic filler, allowing the organosilicon compound to exert its surface treatment effect to a larger extent. Thus the wettability of the treated inorganic filler to the thermosetting resin is significantly improved, and the resulting resin composition is improved in flow and impact resistance.

The first mixing step is a step of mixing two components: (B) and (C). In the step of mixing two components: (B) and (C), only components (B) and (C) may be mixed. Alternatively, the organosilicon compound (C) may be diluted with an organic solvent prior to the mixing, for the purposes of preventing the organosilicon compound from hydrolysis before contact with the inorganic filler and uniformly dispersing the organosilicon compound and the inorganic filler.

The organic solvent used for the dilution purpose is preferably one which is inert to components (A) and (C). Suitable solvents include aliphatic hydrocarbons such as hexane, pentane, octane and isooctane and aromatic hydrocarbons such as toluene and xylene, which may be used singly or in admixture. Inter alia, hexane and toluene are preferred because of a low water content therein and availability.

The device used in the first mixing step may be selected as appropriate depending on a volume of loading. Suitable mixers include a Henschel mixer, vertical mixer, Rocking mixer, concrete mixer, Mixaco mixer, Redige mixer, and ball mill.

The first mixing step is carried out preferably at a temperature of 10 to 50° C., more preferably 15 to 30° C. The mixing time is preferably 2 to 20 minutes, more preferably 3 to 10 minutes.

Under these conditions, the inorganic filler is surface treated with the organosilicon compound. The surface treatment is specifically achieved by agitating the inorganic filler and spraying the organosilicon compound thereto through a single-fluid or two-fluid spray nozzle.

The duration from the end of the first mixing step to the start of the second mixing step is preferably within 1 hour, more preferably within 20 minutes. As long as the duration between two mixing steps is within 1 hour, the overall manufacture time becomes short.

The first mixing step is followed by the second mixing step, which is a step of adding component (A) to the premix and mixing all the components. The device used in the second mixing step may be selected as appropriate depending on a volume of loading. The device may be identical with or different from that used in the first mixing step. Preferably the same device as in the first mixing step is used because the treated inorganic filler obtained in the first mixing step is carried over to the second mixing step without any loss. When the same device is used, an operation of scraping off the inorganic filler deposited on the device inner wall with a spatula or scraper may be added prior to the start of the second mixing step.

The second mixing step is carried out preferably at a temperature of 15 to 30° C., more preferably 20 to 25° C. The mixing time is preferably 2 to 20 minutes, more preferably 3 to 15 minutes.

In the second mixing step, not only component (A), but curing agent (D), cure accelerator (E) and other components may also be added to the premix and mixed together.

The thermosetting resin composition obtained through the first and second mixing steps is melt mixed on a heated roll, kneader or extruder, cooled and solidified, and ground to a desired size.

The resulting resin composition is effectively used in the encapsulation of various semiconductor devices. Low-pressure transfer molding is typical of the method for encapsulating a semiconductor device with the resin composition. Desirably, the resin composition is molded over the semiconductor device at 150 to 260° C. for 30 to 180 seconds and post-cured at 150 to 260° C. for 2 to 16 hours.

### EXAMPLE

Examples of the invention are given below by way of illustration and not by way of limitation.

### Example 1

In the first mixing step, a 20-L Henschel mixer was charged with 5,000 g of spherical fused silica (average particle size 15 μm, specific surface area 3.0 g/m², Tatsumori Co., Ltd.). With stirring at 1,500 rpm, 15 g of 2,2-dimethoxy-1-phenyl-1-aza-2-silacyclopentane having the formula (5) below (Shin-Etsu Chemical Co., Ltd.) was sprayed over the silica through a two-fluid nozzle. At the end of spraying, any deposit was scraped off the inner wall of the mixer with a resin spatula, followed by stirring at 1,500 rpm for 3 minutes.

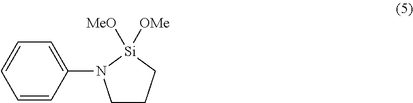 [SMILES: CO[Si]1(OC)CCCN1c1ccccc1]

In the second mixing step, 623.1 g of epoxy resin NC-3000 (Nippon Kayaku Co., Ltd.), 465.1 g of phenolic curing agent MEHC-7851SS (Meiwa Plastic Industries, Ltd.), and 21.8 g of triphenylphosphine (Hokko Chemical Industry Co., Ltd.) as cure accelerator were added to the Henschel mixer loaded with the treated silica, followed by stirring at 3,000 rpm for 3 minutes. The stirred mixture was melt mixed on a heated roll, cooled and solidified, and ground to a desired size, obtaining resin composition #1.

In the following examples, the ingredients from the same suppliers are used unless otherwise stated.

### Example 2

Resin composition #2 was obtained by the same procedure as in Example 1 except that the premix (treated silica) at the end of the first mixing step was allowed to stand at 25° C. for 20 minutes.

### Example 3

Resin composition #3 was obtained by the same procedure as in Example 1 except that the premix (treated silica) at the end of the first mixing step was allowed to stand at 25° C. for 1 hour.

### Example 4

In the first mixing step, a 20-L Henschel mixer was charged with 5,000 g of spherical fused silica (average particle size 15 μm, specific surface area 3.0 g/m²). With stiffing at 1,500 rpm, a mixture of 14.85 g of 2,2-dimethoxy-1-phenyl-1-aza-2-silacyclopentane having formula (5) and 0.15 g of N-phenyl-γ-aminopropyltrimethoxysilane (Shin-Etsu Chemical Co., Ltd.) was sprayed over the silica through a two-fluid nozzle. At the end of spraying, any deposit was scraped off the inner wall of the mixer with a resin spatula, followed by stirring at 1,500 rpm for 3 minutes.

In the second mixing step, 623.1 g of epoxy resin NC-3000, 465.1 g of phenolic curing agent MEHC-7851SS, and 21.8 g of triphenylphosphine cure accelerator were added to the Henschel mixer loaded with the treated silica, followed by stirring at 3,000 rpm for 3 minutes. The stirred mixture was melt mixed on a heated roll, cooled and solidified, and ground to a desired size, obtaining resin composition #4.

### Comparative Example 1

In the first mixing step, a 20-L Henschel mixer was charged with 5,000 g of spherical fused silica (average particle size 15 μm, specific surface area 3.0 g/m²). With stirring at 1,500 rpm, 15 g of N-phenylmaminopropyltrimethoxysilane (Shin-Etsu Chemical Co., Ltd.) was sprayed over the silica through a two-fluid nozzle. At the end of spraying, any filler deposit was scraped off the inner wall of the mixer with a resin spatula, followed by stirring at 1,500 rpm for 3 minutes.

In the second mixing step, 623.1 g of epoxy resin NC-3000, 465.1 g of phenolic curing agent MEHC-7851SS, and 21.8 g of triphenylphosphine as cure accelerator were added to the Henschel mixer loaded with the treated silica, followed by stirring at 3,000 rpm for 3 minutes. The stirred mixture was melt mixed on a heated roll, cooled and solidified, and ground to a desired size, obtaining resin composition #5.

### Comparative Example 2

A 20-L Henschel mixer was charged with 5,000 g of spherical fused silica (average particle size 15 μm, specific surface area 3.0 g/m²), then with 623.1 g of epoxy resin NC-3000, 465.1 g of phenolic curing agent MEHC-7851SS, and 21.8 g of triphenylphosphine as cure accelerator, followed by stirring at 3,000 rpm for 3 minutes. The stirred mixture was melt mixed on a heated roll, cooled and solidified, and ground to a desired size, obtaining resin composition #6.

The resin compositions #1 to #6 were measured for spiral flow and fracture toughness, with the results shown in Table 1.

Spiral Flow

A flow distance of resin material was measured using a mold according to EMMI 66-1 standards, under conditions: mold temperature 175° C., molding pressure 6.9 N/mm², and molding time 120 seconds.

Fracture Toughness

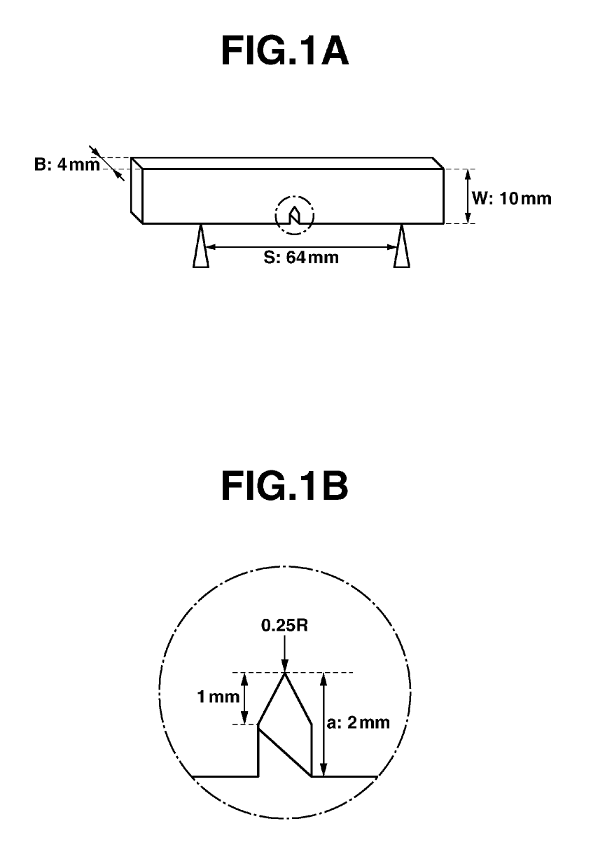

Each composition was transfer molded according to ASTM E399 standards under conditions: 175° C., 120 seconds, molding pressure 6.9 MPa, and post-cured at 180° C. for 4 hours. There is obtained a three-point bending test specimen which was dimensioned and notched as shown in FIGS. 1A and 1B. Using an autograph, a fracture test was performed on the specimen at 260° C. A fracture toughness (K_{1C}) value was computed from a fracture strength (Pc) according to the following equation.

K_{1C}=(3Pc×S×a^{1/2})/(2B×W²)

Pc: fracture strength

S: support span

a: notch length

B: specimen width

W: specimen thickness

TABLE 1

| | | | | | Comparative | |
|---|---|---|---|---|---|---|
| | Example | | | | Example | |
| | 1 | 2 | 3 | 4 | 1 | 2 |
| Resin | # 1 | # 2 | # 3 | # 4 | # 5 | # 6 |
| composition | | | | | | |
| Spiral flow (cm) | 122 | 121 | 120 | 121 | 133 | 68 |
| Fracture | 0.52 | 0.51 | 0.52 | 0.51 | 0.43 | 0.39 |
| toughness K_{1C} | | | | | | |
| (MPa · cm^{1/2}) | | | | | | |

As seen from the results in Table 1, Examples 1 to 4 eliminate a need for room temperature holding or heat treatment after the surface treatment of inorganic filler because of a high rate of reaction of component (C) with the surface of inorganic filler as component (B). The inorganic filler (B) treated with component (C) is highly reactive with the thermosetting resin (A), providing a resin composition with improved flow and impact resistance.

In contrast, the compositions of Comparative Examples 1 and 2 which do not contain the organosilicon compound having formula (1) show a low fracture toughness value and poor impact resistance.

Japanese Patent Application No. 2017-207850 is incorporated herein by reference.

Although some preferred embodiments have been described, many modifications and variations may be made thereto in light of the above teachings. It is therefore to be understood that the invention may be practiced otherwise than as specifically described without departing from the scope of the appended claims.

1. A semiconductor encapsulating resin composition comprising
(A) a thermosetting resin,
(B) an inorganic filler, and
(C) an organosilicon compound having the formula (1): 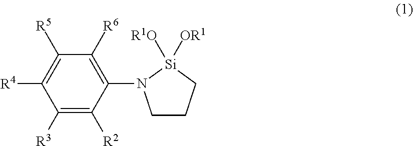
wherein R¹ is a C₁-C₃ alkyl group, R², R³, R⁴, R⁵ and R⁶ are each independently selected from hydrogen, C₁-C₃ alkyl groups, and C₁-C₃ alkoxy groups.

2. The resin composition of claim 1 wherein component (C) contains an organosilicon compound having the formula (2): 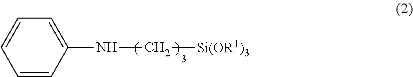
wherein R¹ is a C₁-C₃ alkyl group, in addition to the organosilicon compound having formula (1).

3. The resin composition of claim 1 wherein the thermosetting resin is at least one member selected from among epoxy resins, cyanate resins, and bismaleimide resins.

4. The resin composition of claim 1, further comprising (D) a curing agent and (E) a cure accelerator.

5. A semiconductor device encapsulated with the resin composition of claim 1.
